(19) United States
(12) Patent Application Publication
(10) Pub. No.: US 2015/0050482 A1
(43) Pub. Date: Feb. 19, 2015

(54) GRAPHENE SYNTHESIS BY SUPPRESSING EVAPORATIVE SUBSTRATE LOSS DURING LOW PRESSURE CHEMICAL VAPOR DEPOSITION

(71) Applicants: Rodney S. Ruoff, Austin, TX (US); Shanshan Chen, Xiamen (CN)

(72) Inventors: Rodney S. Ruoff, Austin, TX (US); Shanshan Chen, Xiamen (CN)

(21) Appl. No.: 13/967,237

(22) Filed: Aug. 14, 2013

(51) Int. Cl. C01B 31/04; C30B 25/18; C30B 25/16

(52) U.S. Cl. CPC C01B 31/0461; C30B 25/165; C30B 25/18; C30B 29/02
USPC 428/220; 117/102

(57) ABSTRACT

Method for synthesizing large single-crystal graphene films by suppressing evaporative substrate loss in chemical vapor deposition, and graphene films synthesized thereby. The substrate may be configured as a tube prior to exposure to an organic compound at high temperature. Low flow rate of the gaseous carbon source may be employed, and this flow rate may be increased after an initial nucleation period.

### STATEMENT OF GOVERNMENT INTEREST

At least portions of this invention were made using U.S. government funding provided by the National Science Foundation under grant number 1006350 and by the Office of Naval Research. The U.S. government has certain rights in the invention.

### TECHNICAL FIELD

The present disclosure relates to synthesis of graphene films by chemical vapor deposition, and in particular to methods of synthesizing single-crystal graphene films under conditions in which evaporative loss of the substrate is suppressed by configuration of the substrate.

### TECHNICAL BACKGROUND

Graphene is a carbon allotrope configured as a single planar sheet of sp²-bonded carbon atoms arranged in a two-dimensional honeycomb crystal lattice. Graphene is characterized by extremely high strength and electron mobility and low weight. These and other physical and chemical properties make it an attractive candidate for industrial applications.

Several techniques for the production of graphene monolayers have been described, including mechanical exfoliation of graphite and epitaxial growth on silicon carbide substrates. Mechanical exfoliation is expensive and not practicably scalable for industrial applications. Silicon carbide reduction processes involve heating SiC to high temperatures (e.g. much grater than 1400° C.) to evolve silicon atoms from the SiC surface to form graphene layers. The size of the graphene samples so produced is dependent upon the size of the SiC substrate. Moreover, the quality of the graphene so produced degrades at the crystallographic step edges. Even if SiC graphene production was scalable to large diameter crystals, it is not possible to isolate graphene from the SiC substrate for use in applications not compatible with such substrates.

Monolayer graphene films have been synthesized on metal substrates by chemical vapor deposition (CVD), in which generally a metal substrate is exposed to gaseous hydrocarbon precursors which decompose onto the substrate to produce graphene layers. These CVD processes have typically yielded polycrystalline graphene films composed of relatively small graphene domains and a high density of graphene domain boundaries. Such domain boundaries are associated with diminished strength, electrical mobility, thermal conductivity, and oxidation resistance of graphene films.

Accordingly, there is a need in the art for a process for the synthesis of free-standing graphene films with minimal domain boundary-associated defects that is scalable for production of industrial quantities of graphene.

### SUMMARY

In accordance with the purpose(s) of the invention, as embodied and broadly described herein, this disclosure, in one aspect, relates to graphene films, and specifically to processes for making millimeter-size graphene films and the graphene films made thereby.

In one aspect, the present disclosure provides a method of synthesizing graphene films on substrates configured to suppress evaporative loss of the substrate during chemical vapor deposition. In another aspect, the present disclosure provides millimeter-size, single-crystal graphene films formed by a processing including configuring a substrate to minimize evaporative loss of the substrate during chemical vapor deposition.

Additional aspects of the invention will be set forth in part in the description which follows, and in part will be obvious from the description, or can be learned by practice of the invention. The advantages of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE FIGURES

The accompanying figures, which are incorporated in and constitute a part of this specification, illustrate several aspects and together with the description serve to explain the principles of the invention.

FIG. 1 illustrates an apparatus for synthesizing graphene using the processes of the disclosed subject matter according to one aspect of the present disclosure.

FIG. 2 is a flowchart of a prior art method of graphene synthesis by chemical vapor deposition.

FIG. 3 is a flowchart of an exemplary method of graphene synthesis by chemical vapor deposition according to one aspect of the present disclosure.

FIG. 4 is (A) a scanning electron micrograph of a large single-crystal graphene film grown on the inner surface of a copper tube; (B) a scanning electron micrograph of graphene grown on the outer surface of the copper tube; (C) an atomic force microscopy image of the graphene film shown in (A); (D) an atomic force microscopy image of the graphene shown in (B); and (E) liner profiles taken along the diagonal lines superimposed on (C) and (D) of the variation in height of the graphene from (A) and (B).

FIG. 5 is (A) an optical micrograph of a field of view taken from a millimeter-size graphene domain (shown in inset) synthesized according to one aspect of the present disclosure; and (B) a representative Raman spectrum taken from the circled region of the graphene domain in (A).

FIG. 6 is (A) an atomic force micrograph of non-annealed Cu foil prior to graphene synthesis; (B) an atomic force micrograph of pre-annealed Cu foil prior to graphene synthesis; (C) a plot of line profiles of height across the lines superimposed on (A) and (B); (D) a scanning electron micrograph of graphene domains grown on the inner surface of the non-annealed Cu foil; and (E) a scanning electron micrograph of graphene domains grown on the inner surface of the pre-annealed Cu foil.

FIG. 7 is a series of transmission electron microscopy selected area electron diffraction images from a single domain of graphene synthesized on the inner surface of a Cu foil tube according to one aspect of the present disclosure.

FIG. 8 is a plot of drain current versus gate voltage of a graphene based field-effect transistor constructed using graphene synthesized according to one aspect of the present disclosure.

### DESCRIPTION

The present invention can be understood more readily by reference to the following detailed description of the invention and the Examples included therein.

Before the present compounds, compositions, articles, systems, devices, and/or methods are disclosed and described, it is to be understood that they are not limited to specific synthetic methods unless otherwise specified, or to particular reagents unless otherwise specified, as such can, of course, vary. It is also to be understood that the terminology used herein is for the purpose of describing particular aspects only and is not intended to be limiting. Although any methods and materials similar or equivalent to those described herein can be used in the practice or testing of the present invention, example methods and materials are now described.

### DEFINITIONS

As used in the specification and the appended claims, the singular forms “a,” “an” and “the” include plural referents unless the context clearly dictates otherwise. Thus, for example, reference to “a solvent” includes mixtures of two or more solvents.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “optional” or “optionally” means that the subsequently described event or circumstance can or can not occur, and that the description includes instances where said event or circumstance occurs and instances where it does not.

Throughout this specification, unless the context requires otherwise, the word “comprise,” or variations such as “comprises” or “comprising,” will be understood to imply the inclusion of a stated integer or step or group of integers or steps but not the exclusion of any other integer or step or group of integers or steps.

As briefly discussed above, in one embodiment in accordance with the present disclosure, a method for synthesizing graphene films by suppressing evaporative loss of the substrate during low pressure chemical vapor deposition is provided.

The present disclosure provides, in various aspects, high-quality, single-crystal graphene films having a diameter or diagonal length of 1 mm or more, and processes for synthesizing such films. In one aspect, these graphene films are composed of single crystals to minimize the deleterious effects of defects associated with grain boundaries. In another aspect, these films have a diameter of 1 mm of more. In another aspect, the methods of synthesis of these graphene films are cost-effective and scalable for industrial application. In another aspect, the single crystal graphene films disclosed herein are high quality, exhibiting a carrier mobility of greater than about 5000 cm² V⁻¹ s⁻¹.

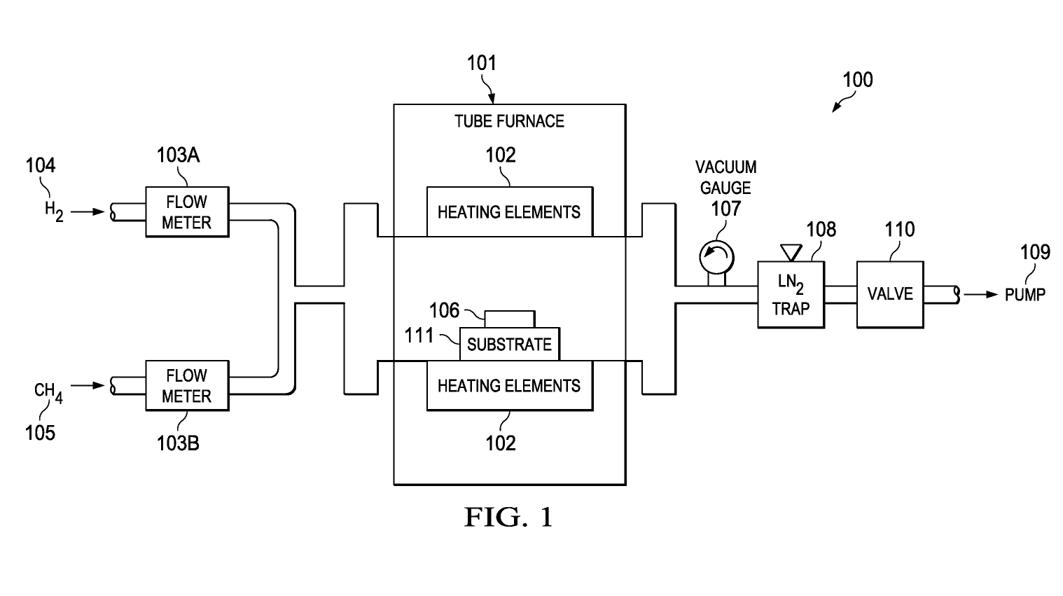

FIG. 1 illustrates an exemplary CVD apparatus for synthesizing graphene films using the processes of the present disclosure. Apparatus 100 includes a tube furnace 101, which is an electric heating device used to conduct synthesis of graphene. In one embodiment, tube furnace 101 consists of a cylindrical cavity surrounded by heating elements 102 (e.g., heating coils), which are embedded in a thermally insulating matrix (not shown). In one embodiment, the length of the cylindrical cavity is between 40 to 60 cm with a diameter of about 8 cm. The temperature of tube furnace 101 may be controlled via feedback from a thermocouple (not shown). The growth chamber used to grow graphene can be a furnace as described above that can be scaled to any size as required by the size of the substrate and the size of the graphene to be grown. Alternatively, a cold wall single wafer apparatus can be used to grow graphene which can be heated to an appropriate temperature to react with the reacting gas on the surface of the substrate.

Apparatus 100 may further include flow meters 103A, 103B used to measure the gas flow. For example, flow meter 103A is used to measure the flow of hydrogen (H₂) gas 104; whereas, flow meter 103B is used to measure the flow of a gaseous carbon source such as methane 105.

Apparatus 100 may also include a vacuum gauge 107 used to measure the pressure in a vacuum. Additionally, apparatus 100 may include a trap 108 used to condense all vapors except the permanent gases into a liquid or solid. Trap 108 prevents vapors from contaminating a vacuum pump 109. In one embodiment, trap 108 uses liquid nitrogen (LN₂) as its coolant. Apparatus 100 additionally includes a ball valve 110 used to control the pressure.

Although reference is made above to one exemplary CVD apparatus, the present disclosure is not limited to a particular apparatus or system for CVD processes. The principles of the present disclosure may be implemented by any means for CVD, including, without limitation, heating the substrate surface using rapid thermal processing or flash annealing or by use of a cold wall chamber, as understood by persons of ordinary skill in the art in light of the present disclosure. Additionally, while reference is made to specific parameters, including dimensions of the CVD apparatus and substrate, the present disclosure is not limited to these parameters, but rather extends to all parameters and dimensions practicable according to the principles of the present disclosure.

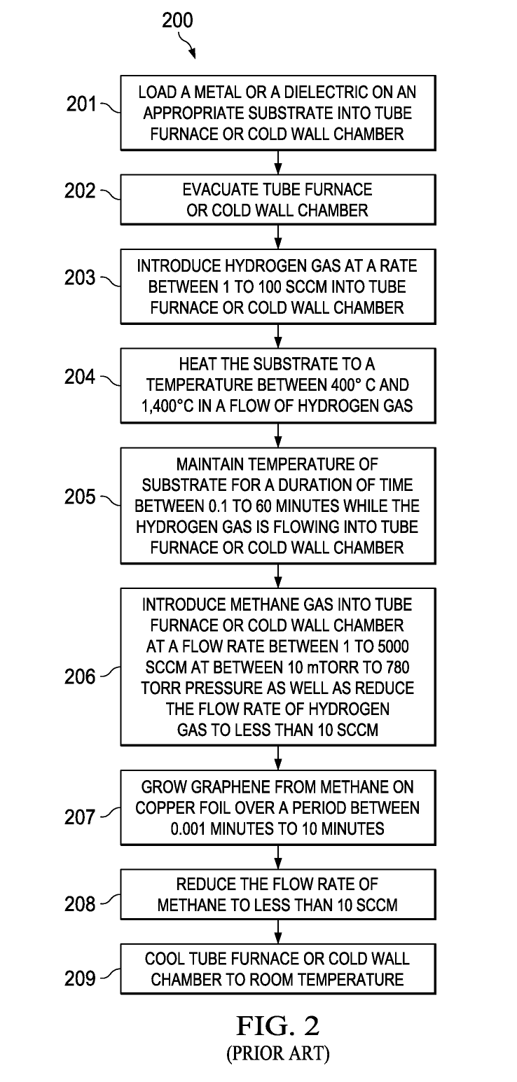

With reference to U.S. Pat. No. 8,470,400, hereby incorporated by reference in its entirety, CVD techniques have been employed to grow graphene films on metal substrates having a diameter on the order of 100 μm². FIG. 2 depicts an exemplary flowchart of a prior art method of CVD synthesis of graphene films. As depicted, in step 201, a metal substrate (e.g., foil of copper 106) or a dielectric on an appropriate substrate is loaded into tube furnace 101 or into a cold wall chamber. In step 202, tube furnace 101 or the cold wall chamber is evacuated. In step 203, a rate of hydrogen gas 104 between 1 to 100 sccm is introduced into tube furnace 101 or the cold wall chamber. In step 204, the substrate is heated to a temperature between 400° C. and 1,400° C. in a flow of hydrogen gas 104. In step 205, the temperature of the substrate in step 204 is maintained for a duration of time between 0.1 to 60 minutes while the hydrogen gas 104 is flowing into tube furnace 101 or the cold wall chamber. In step 206, methane 105 or some other organic compound is introduced into tube furnace 101 or the cold wall chamber at a flow rate between 1 to 5,000 sccm at between 10 mTorr to 780 Torr of pressure. Furthermore, in step 206, the flow rate of hydrogen gas 104 is reduced to less than 10 sccm. In step 207, graphene is grown from methane 105 on copper foil 106 over a period between 0.001 minutes to 10 minutes. In step 208, the flow rate of methane 105 is reduced to less than 10 sccm. In step 209, tube furnace 101 or the cold wall chamber is cooled to room temperature.

In one aspect according to the disclosed subject matter, an improved method of single-crystal graphene synthesis by CVD is disclosed. In one aspect of the improved method, the metal CVD substrate is pre-configured to form a partially confined interior surface of the substrate. For the purpose of the present disclosure, “partial confinement” of the confined interior space of the substrate refers to the preserved access of the low pressure gaseous environment of the CVD apparatus to and from the interior surface, such that fluid communication is maintained between the confined interior surface and the environment surrounding the substrate. For example, and as discussed below, the metal substrate can be configured as a cylindrical tube, wherein the interior of the substrate is partially confined with respect to the interior surface diameter of the tube but still exposed to the surrounding atmospheric conditions at the open ends of the tube.

According to one aspect of the present disclosure, a method is provided for graphene synthesis on a metal substrate configured to minimize evaporative substrate loss. The metal substrate may be configured in any manner suitable to provide a partially confined interior surface that remains partially exposed to the flow of gas through the CVD apparatus. In one aspect, the metal substrate is configured as a tube. In another aspect, the metal substrate may be configured into a non-cylindrical tube, such as polyhedral prism configurations, including triangular prisms, square or rectangular prisms, pentagonal prisms and so forth.

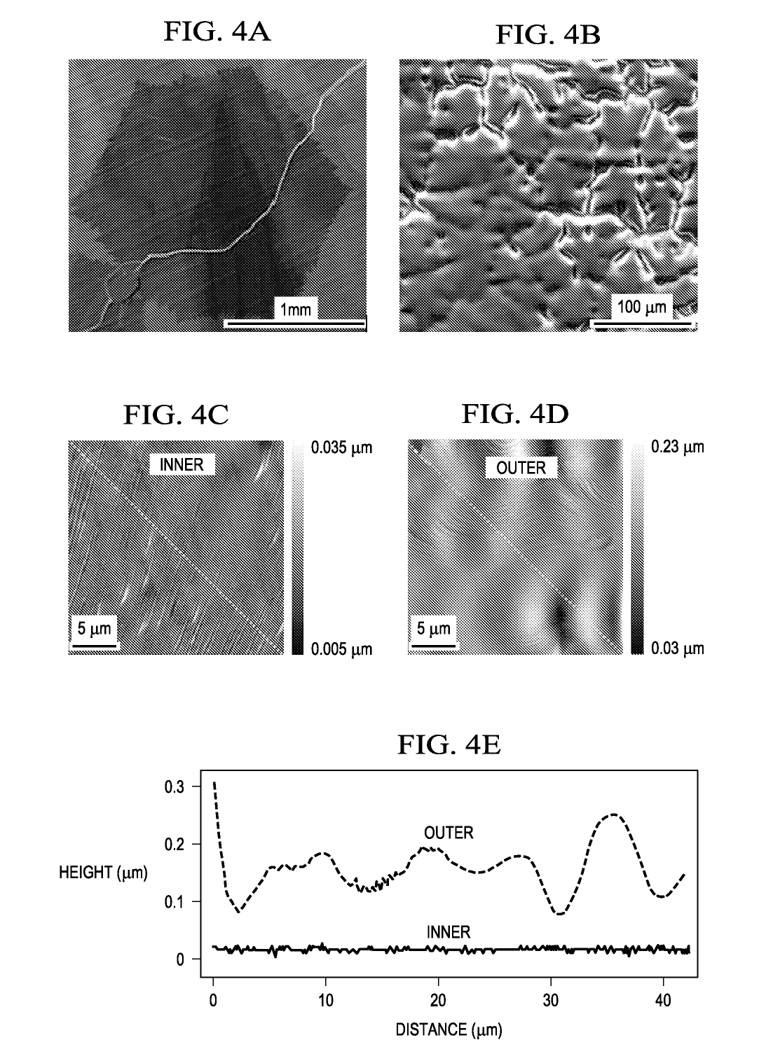

Without wishing to be limited by theory, it is believed that providing a partially confined interior space results in suppression of evaporative loss of the substrate on the confined interior surface. In one aspect of the present disclosure, evaporative loss of the substrate is in equilibrium or near equilibrium with re-deposition of the substrate, such that the surface integrity of the confined interior surface of the substrate is maintained. This preserved substrate surface integrity is illustrated in FIG. 4C as contrasted with FIG. 4D, discussed below in Example 1.

In one aspect of the present disclosure, the metal substrate is a copper foil. Copper foils are relatively inexpensive, readily electropolished, and easily configured to provide a confined interior surface. In alternative embodiments, the metal substrate is a configured sheet or piece of any suitable metal or alloy, including, without limitation, copper, cobalt, nickel, ruthenium, rhodium, platinum, or iridium, or alloys thereof.

The dimensions of the substrate can be varied as desired, the primary limiting factor being the dimensions of the CVD apparatus. In one embodiment, the metal substrate has a length of between about 1 cm and about 10 cm and a width of about 1 cm to about 10 cm. Where the substrate is configured into a tube or the like, the internal diameter of the substrate may be, for example, between 0.1 cm and about 1 cm One of ordinary skill in the art will be able to optimize the substrate dimensions according to the application in light of the present disclosure.

In one aspect of the present disclosure, the metal substrate is electropolished prior to configuration or prior to loading into the CVD apparatus. An exemplary electropolishing protocol is provided in Example 1.

In another aspect of the disclosed subject matter, graphene growth is carried out under a low flow rate and partial pressure of the gaseous carbon source. Without limitation by theory, it is believed that these conditions result in reduced density of graphene nucleation on the substrate. Reduced nucleation density is desirable because it prevents the “crowding” and overlap of developing single-crystal graphene films into polycrystalline structures with domain boundaries and associated reductions in strength, electrical mobility, thermal conductivity, and oxidation resistance.

Additionally or alternatively, the flow rate of the carbon source may be adjusted after an initial “seeding” or nucleation phase of the substrate. After low density nucleation of the substrate is achieved, the flow rate of the gaseous carbon source can be increased to achieve complete coverage of the substrate. Graphene will preferentially deposit at the formed graphene nuclei after the initial nucleation phase, such that new nuclei (which may result in undesirable domain boundaries) are not formed on the substrate. In one embodiment, the flow rate of the gaseous carbon source may be increased from an initial flow rate of about 0.1-1 sccm for at least about the first 10-100 minutes of CVD graphene synthesis to about 1-100 sccm of the gaseous carbon source for the duration of the graphene synthesis.

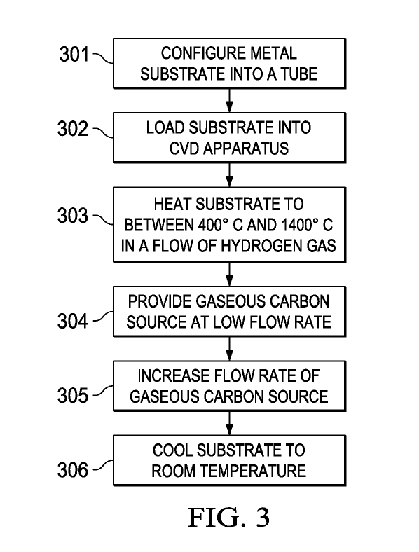

Accordingly, in one exemplary aspect of the present disclosure, as illustrated in FIG. 3, a method 300 is provided in which:

a metal substrate is (optionally) electropolished, then configured at step 301 into a tubular or prismatic configuration having a confined interior space such that the interior diameter of the substrate is not exposed but the end faces of the substrate are open;

the metal substrate is loaded into a CVD apparatus at step 302;

the metal substrate and heated to between about 400° C. to about 1400° C. and is subject to a hydrogen anneal for a duration of about 0.1 min to about 100 min at a flow rate of between about 1 sccm to about 100 sccm at a partial pressure of about 10 mTorr to about 780 Torr at step 303;

a gaseous carbon source is introduced at a flow rate between about 0.1 sccm to about 10 sccm at a partial pressure of about 1 mTorr to about 100 mTorr for a duration of at least about 10 min at step 304, the flow rate and partial pressure of hydrogen optionally being adjusted upon introduction of the gaseous carbon source;

the flow rate and partial pressure of the gaseous carbon source is optionally increased at step 305, the flow rate and partial pressure of hydrogen optionally being adjusted upon increase of the flow rate of the gaseous carbon source; and

the substrate is cooled to room temperature at step 306.

Method 300 may include other and/or additional steps that, for clarity, are not depicted. Further, method 300 may be executed in a different order presented and the order presented in the discussion of FIG. 3 is illustrative. Additionally, certain steps in method 300 may be executed in a substantially simultaneous manner or may be omitted.

A gaseous carbon source is employed in the CVD graphene synthesis processes of the present disclosure. Any gaseous carbon source subject to decomposition and concomitant carbon deposition may be employed. In certain embodiments, the gas is a gaseous hydrocarbon. For the purpose of the present disclosure, a gaseous hydrocarbon is any gas comprising at least one carbon atom. The processes described in the present disclosure can include the use of any organic compound that can be a source of carbon. Additionally or alternatively, an inert gas bubbled through a liquid organic compound such that the inert gas carries carbon-containing atoms through the CVD apparatus may be employed. Although reference is made to methane gas in the non-limiting examples below and the exemplary methods described above, one of ordinary skill in the art will be able to employ any gaseous carbon source, and to optimize the partial pressure and flow rate of the gaseous carbon source, based on the present disclosure by routine optimization.

In another aspect of the present disclosure, large single-crystal graphene films of high quality produced by the methods described above and exemplified herein are disclosed. These films can have a diagonal length of about 0.5 mm to about 10 mm, or about 0.5 mm to about 5 mm, or about 0.5 mm to about 3 mm, or about 0.5 mm to about 2 mm. Additionally, these films can exhibit a carrier mobility of about 2000 cm² V⁻¹ s⁻¹ to about 6000 cm² V⁻¹ s⁻¹, or about 2000 cm² V⁻¹ s⁻¹ to about 5500 cm² V⁻¹ s⁻¹, or about 2000 cm² V⁻¹ s⁻¹ to about 5200 cm² V⁻¹ s⁻¹.

Without being limited by theory, it is believed that the partially confined interior space of the metal substrate in accordance with one aspect of the present disclosure results in decreased nucleation density of graphene grains during graphene synthesis, permitting growth of large, high quality single-crystal graphene films. As discussed, re-deposition of atoms of substrate that are evaporated during the low-pressure, high-temperature CVD process results in a smoother substrate surface than prior art CVD graphene synthesis methods. Additionally, and still without limitation by theory, it is possible that as the atoms of the substrate re-deposit on the partially confined interior substrate surface, they deposit on top of small graphene grains before they expand. Both the increased substrate smoothness and this re-deposition on top of smaller graphene grains may play a part in the decreased nucleation density of graphene observed on the partially confined interior space.

Certain aspects of the present disclosure are further described and illustrated in Millimeter-Size Single-Crystal Graphene by Suppressing Evaporative Loss of Cu During Low Pressure Chemical Vapor Deposition by S. Chen et al., ADVANCED MATERIALS 25:14, 2062-2065, 2013 (and the supplemental information thereto), hereby incorporated herein in its entirety.

The present application is further described by means of the example, presented below. The use of such examples is illustrative only and in no way limits the scope and meaning of the disclosed subject matter or of any exemplified term.

### Example 1

### Substrate Preparation

25 um thick Cu foil sheets (99.8% Alfa Aesar No. 13382) were electropolished using an electrochemical cell to smooth the surface and remove a coating layer applied by the manufacturer. The Cu foils were used as the anode with a large Cu plate as the cathode. The electropolishing solution was composed of 300 mL of water, 150 mL of ortho-phosphoric acid, 150 mL of ethanol, 30 mL of isopropyl alcohol, and 3 g of urea. The foils were placed into the solution while supported by an alligator clip. A Hewlett-Packard 6612 System DC power supply was used to supply constant voltage/current, and a voltage in the range of 3.0-6.0 V was applied for 90 seconds. After electropolishing, the Cu foils were rinsed with deionized water, further washed with ethanol, and finally blow-dried with nitrogen. Subsequently, the Cu foils were wrapped into a tube with a diameter of 0.5 cm and a length of 5 cm.

### Hydrogen Anneal and Graphene Growth

Each Cu tube was loaded into a one inch quartz tube furnace. The furnace was heated to 1035° C., and a hydrogen gas flow of 2 sccm at a partial pressure of 22 mTorr was provided for 15 minutes (“hydrogen anneal”) to prevent hydrogen embrittlement. Following the hydrogen anneal, graphene growth was carried out at a methane flow rate of 0.1 sccm (with a partial pressure of 9 mTorr) and a hydrogen flow rate of 10 sccm (with a partial pressure of 65 mTorr) for six hours. The Cu tubes were then cooled to room temperature and removed.

As controls, graphene growth was performed for 90 minutes (to permit analysis of nucleation density) according to the same conditions on: (a) a Cu tube which was not subject to hydrogen annealing; and on (b) Cu tube which was pre-annealed before loading into the tube furnace.

### Analysis

The topography of both the inner surface and the outer surface of the copper tubes were measured using contact-mode atomic force microscopy (AFM) (Veeco, Auto-probe CP Research System). Optical and scanning electron micrographs of the synthesized graphene were taken, and Raman spectroscopy was used to characterize the quality, thickness, and uniformity of the graphene domains. The structure of the graphene domains was determined by transmission electron microscopy (JEM-2010F). The domains were transferred to a Quantifoil holey carbon supported grid and surveyed by obtaining selected area electron diffraction (SAED) data from every square in the grid.

To measure the electron transport properties of the graphene, the sheets were transferred onto a highly doped p-type silicon substrate with a 300 nm think silicon oxide layer and then contacted by e-beam lithography and a metallization process to define the external and drain electrodes to formed graphene-based back gate field-effect transistors. A typical channel width and length were 4.2 μm and 18.1 μm, respectively. The electron transport properties were then measured by a Lakeshore probe station with an Agilent 4155 C in ambient condition at room temperature after transfer of the sheets. The source-drain conductance was measured at room temperature as a function of back-gate voltage.

### Results

As shown in FIG. 4A, graphene crystals having a diagonal length of over 2 mm were synthesized on the inner surface of the Cu tube by the methods described above, while significantly smaller graphene domains were observed on the outer surface of the tube, as shown in FIG. 4B. AFM images of the crystals grown on the inner (FIG. 4C) and outer (FIG. 4D) surfaces of the tube showed that the graphene crystals grown on the inner surface of the tube exhibited minimal fluctuations in height, while the crystals grown on the outer surface of the tube exhibited substantial fluctuations in height. Line profiles of the height of the crystals (corresponding to the heights of the lines shown in FIGS. 4C and 4D) are provided in FIG. 4E. These data indicate that the confined inner surface of the substrate is much smoother than the outer surface due to suppressed evaporative loss of the substrate, and that this improved smoothness is associated with flatter graphene domains after synthesis.

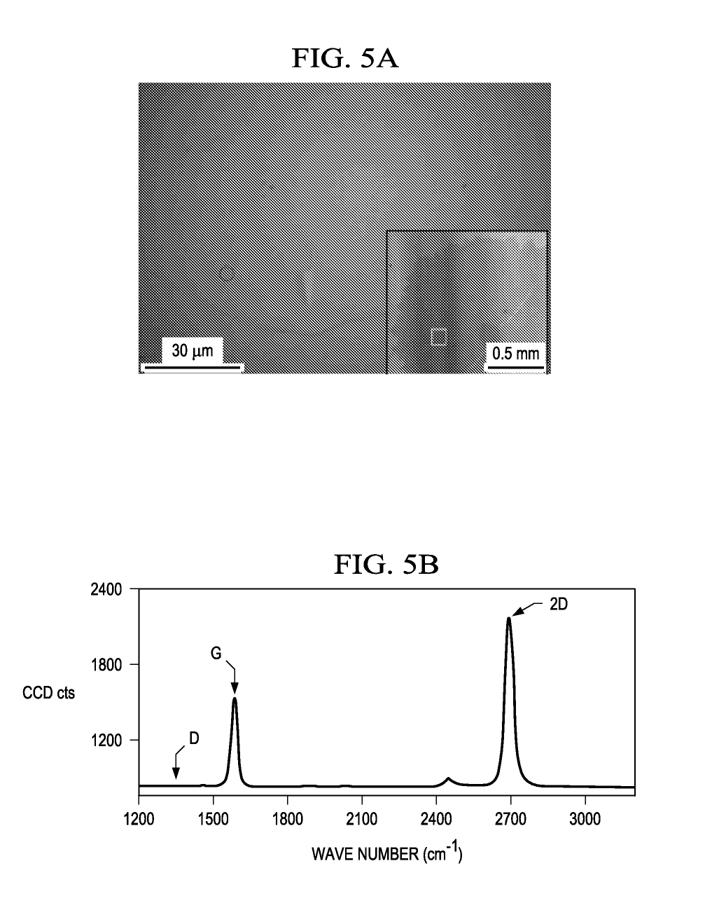

Optical micrographs of a portion of a millimeter-size graphene domain grown on the interior surface of a Cu foil tube was transferred onto a 300 nm silicon dioxide/silicon substrate indicate uniform thickness. As shown in FIG. 5A, a micrograph of a region with a small crack exhibits uniform optical contrast of the graphene sheet, indicating uniform thickness. A representative Raman spectrum of the graphene domain provided in FIG. 5B exhibits sharp G and 2D peaks, with a small G/2D peak ration of approximately 0.3. This spectrum shows that the film is a single layer graphene sheet. Furthermore, the disorder-induced D band is not detected on the graphene sheet, indicating a high-quality film.

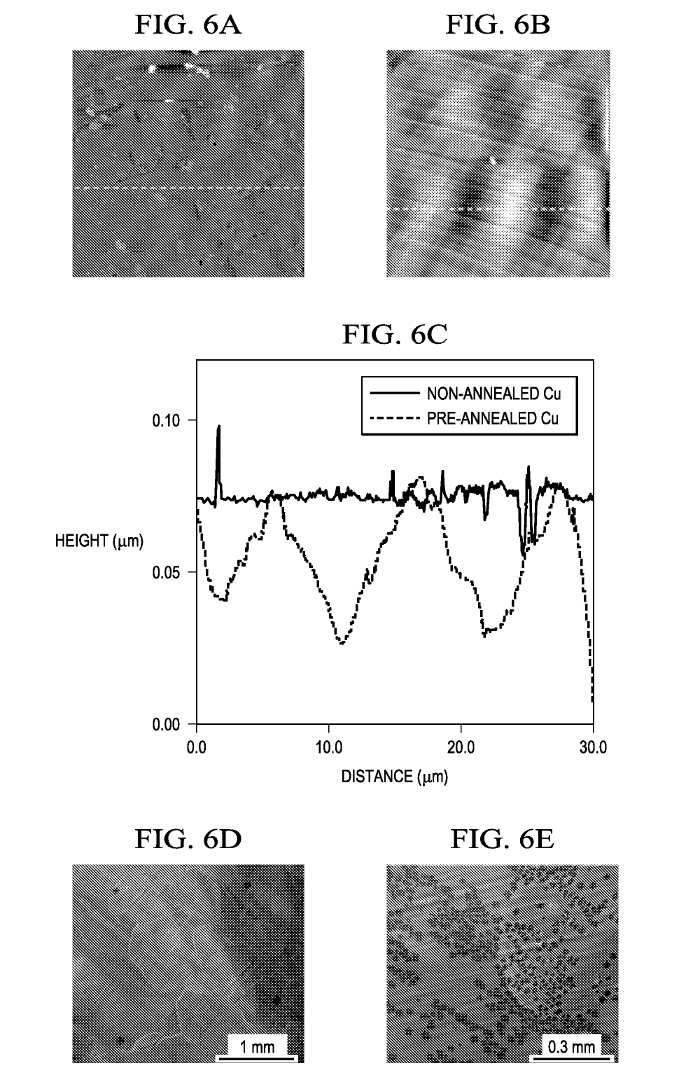

AFM analysis of the non-annealed (FIG. 6A) and pre-annealed (FIG. 6B) Cu foil controls prior to graphene synthesis revealed that the pre-annealed Cu foil (annealed outside the CVD apparatus) in particular exhibited significant evaporation-assisted roughness, as shown in the pronounced height deviations in the line plots of height in FIG. 6C. SEM images of the non-annealed foil (FIG. 6D) and pre-annealed foil (FIG. 6E) after graphene synthesis for 90 minutes show higher graphene nucleation density on the rough pre-annealed foil, supporting the inference that surface roughness is associated with higher graphene nucleation density.

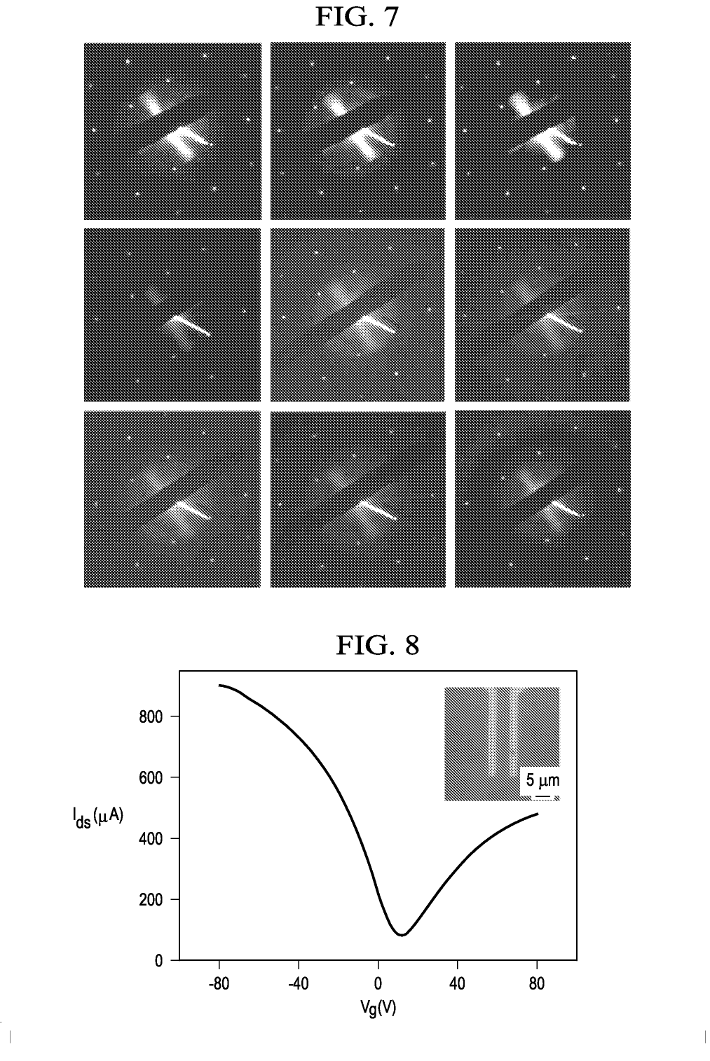

SAED images of randomly selected points within discrete regions of a single graphene crystal are provided in FIG. 7. The SAED survey showed that each graphene domain has only a single, uniform SAED pattern, i.e. a single crystallographic orientation, that matches the pattern expected for monolayer graphene.

FIG. 8 shows the typical source-drain current (I_{ds}) curves at different gate voltages (Vg). As understood by those of skill in the art, the field effect mobility of graphene sheets (μ) can be achieved using the following equation:

$${R}_{tot} = {R}_{contact} + \frac{L / W}{ne μ}$$

Where Rₜₒₜ is the total resistance of the device, and the contact resistance R_{contact} consists of the uncovered graphene section resistance and the metal graphene contact resistance, respectively. L is the channel length, W is the channel width, and n is the carrier concentration in the graphene channel region. The R_{contact} was deduced through the saturation value of I_{ds}−V_{g} curves (˜150 ohm), which is the same as the R_{contact} determined by four-probe measurements for similar devices.

The mobility for the graphene crystals synthesized on the inner surface of the Cu foils was found to be up to 5200 cm² V⁻¹ s⁻¹, with typical values in the range of 2000 to 5200 cm² V⁻¹ s⁻¹.

It will be apparent to those skilled in the art that various modifications and variations can be made in the present invention without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A method of synthesizing graphene films, the method comprising:
configuring a metal substrate to form a partially confined interior surface of the substrate in fluid communication with a gaseous environment surrounding the metal substrate; and
loading the metal substrate into a chemical vapor deposition apparatus;
heating the metal substrate to a temperature between 400° C. to about 1400° C.;
providing hydrogen gas while maintaining the temperature of the substrate; and
providing a gaseous carbon source at a flow rate of about 0.1 sccm to about 10 sccm and a pressure of about 1 mTorr to about 100 mTorr through the chemical vapor deposition apparatus while maintaining the temperature of the substrate,
wherein carbon atoms from the gaseous carbon source are deposited onto the confined interior surface of the substrate to form graphene films having a diagonal length of at least about 1 mm.

2. The method of claim 1, further comprising:
providing hydrogen gas into the chemical vapor deposition for about 0.1 minutes to about 100 minutes prior to providing the gaseous carbon source.

3. The method of claim 2, further comprising:
increasing the hydrogen flow rate and partial pressure upon providing the gaseous carbon source.

4. The method of claim 1, further comprising increasing the flow rate and partial pressure of the gaseous carbon source at least about 10 minutes after the gaseous carbon source is provided.

5. The method of claim 1, wherein the metal substrate is configured as a tube.

6. The method of claim 1, wherein the gaseous carbon source is a hydrocarbon.

7. The method of claim 6, wherein the gaseous carbon source is methane.

8. The method of claim 1, wherein the gaseous carbon source is a noble gas bubbled through an organic liquid.

9. The method of claim 1, wherein the metal substrate is selected from the group consisting of copper, cobalt, nickel, ruthenium, rhodium, platinum, or iridium.

10. The method of claim 1, wherein the metal substrate is copper.

11. The method of claim 1, wherein the metal substrate is a foil sheet.

12. A graphene film having a diagonal length greater than 1 mm and an electron mobility between about 2000 cm² V⁻¹ s⁻¹ and about 5200 cm² V⁻¹ s⁻¹ made by a method comprising:
configuring a metal substrate to form a partially confined interior surface of the substrate in fluid communication with a gaseous environment surrounding the metal substrate; and
loading the metal substrate into a chemical vapor deposition apparatus;
heating the metal substrate to a temperature between 400° C. to about 1400° C.;
providing hydrogen gas while maintaining the temperature of the substrate; and
providing a gaseous carbon source at a flow rate of about 0.1 sccm to about 10 sccm and a pressure of about 1 mTorr to about 100 mTorr through the chemical vapor deposition apparatus while maintaining the temperature of the substrate,
wherein carbon atoms from the gaseous carbon source are deposited onto the confined interior surface of the substrate to form the graphene film.

13. The graphene film of claim 12, wherein the film is a single-crystal film having a single crystallographic orientation.
